(19) United States
(12) Patent Application Publication
(10) Pub. No.: US 2025/0324912 A1
(43) Pub. Date: Oct. 16, 2025

(54) JOINED BODY AND METHOD FOR MANUFACTURING JOINED BODY

(71) Applicant: NGK INSULATORS, LTD., Nagoya-shi (JP)

(72) Inventor: Takahiro KAWASAKI, Tajimi-shi (JP)

(21) Appl. No.: 19/250,209

(22) Filed: Jun. 26, 2025

Related U.S. Application Data
(63) Continuation of application No. PCT/JP2023/046528, filed on Dec. 25, 2023.

(30) Foreign Application Priority Data
Jan. 27, 2023 (JP) 2023-011415

(51) Int. Cl. H10N 30/00; H10N 30/072; H10N 30/086

(52) U.S. Cl. CPC H10N 30/708; H10N 30/072; H10N 30/086

(57) ABSTRACT

A joined body 1 includes a piezoelectric layer 11a including a piezoelectric material; a dielectric film 13 arranged under the piezoelectric layer 11a; a support substrate 14 joined with the piezoelectric layer 11a via the dielectric film 13; and a sacrificial layer provided between the support substrate 14 and the piezoelectric layer 11a, and capable of including a hollow part 17 formed therein. The dielectric film 13 includes SiO₂ as a main component, and has a H content of 0% or more and 1% or less in terms of atomic ratio. As a result of this, a desired joined body including a hollow part is provided. Further, there is provided a method for manufacturing a joined body, in which the etching rate of the dielectric film is small, and by which the sacrificial layer can be selectively removed during etching.

### CROSS-REFERENCE TO RELATED APPLICATION

This application is a continuation application of PCT/JP2023/046528 filed on Dec. 25.2023, which claims the benefit of priority of Japanese Patent Application No. 2023-011415, filed on Jan. 27, 2023, the entire contents of which are incorporated herein by reference.

### TECHNICAL FIELD

The present invention relates to a joined body, and a method for manufacturing a joined body.

### BACKGROUND ART

As an elastic wave device having a hollow structure, a device is known in which SiO₂ is provided as a dielectric film between a support substrate such as a silicon substrate and a piezoelectric substrate.

PTL 1 discloses an elastic wave apparatus having a hollow structure. The elastic wave apparatus includes a support substrate having a concave part at the upper surface, a thin film provided on the support substrate, a piezoelectric substrate having a first main surface, and a second main surface opposed to the first main surface with the first main surface side arranged on the thin film, and an IDT electrode provided on the second main surface. A cavity surrounded by the support substrate and at least the thin film of the thin film and the piezoelectric substrate is formed, and the thin film is arranged in the area on the first main surface of the piezoelectric substrate, and bonded with the support substrate via the thin film, and at least a partial area of the area above the cavity.

### CITATION LIST

### Patent Literature

PTL 1: WO 2016/147687

### SUMMARY OF INVENTION

### Technical Problem

For forming a hollow structure, for example, the following method is used: a film (sacrificial layer) of a different material from that of the dielectric film is formed in a hollow part, and subsequently, the sacrificial layer is removed by etching from the hole part formed in the support substrate or the piezoelectric substrate.

At this step, a small difference in etching rate between the dielectric film and the sacrificial layer causes a concern that not only the sacrificial layer but also the dielectric film may be etched. As a result, a joined body including a desired hollow part may not be able to be obtained.

It is an object of the present invention to provide a joined body including a desired hollow part. Further, it is another object of the present invention to provide a method for manufacturing a joined body, in which the difference in etching rate from the sacrificial layer is large, and by which the sacrificial layer can be selectively removed during etching.

### Solution to Problem

In order to solve the foregoing problem, the present invention provides a joined body including a piezoelectric layer including a piezoelectric material, a dielectric film arranged under the piezoelectric layer, a support substrate joined with the piezoelectric layer via the dielectric film, and a sacrificial layer provided between the support substrate and the piezoelectric layer, and capable of including a hollow part formed therein, in which the dielectric film includes SiO₂ as a main component, and has a H content of 0% or more and 1% or less in terms of atomic ratio.

Further, the present invention provides a joined body including a piezoelectric layer including a piezoelectric material, a dielectric film arranged under the piezoelectric layer, a support substrate joined with the piezoelectric layer via the dielectric film, and a hollow part provided between the support substate and the piezoelectric layer, in which the dielectric film includes SiO₂ as a main component, and has a H content of 0% or more and 1% or less in terms of atomic ratio.

Still further, the present invention provides a method for manufacturing a joined body, the method including a sacrificial layer forming step of forming a sacrificial layer on a piezoelectric substrate, a dielectric film forming step of forming a dielectric film including SiO₂ as a main component, and having a H content of 0% or more and 1% or less in terms of atomic ratio on the piezoelectric substrate and sacrificial layer, a joining step of joining the dielectric film and the support substrate, a film thinning step of thinning the piezoelectric substrate, and obtaining a piezoelectric layer, and a removing step of removing the sacrificial layer, and forming a hollow part between the support substrate and the piezoelectric layer.

Furthermore, the present invention provides a method for manufacturing a joined body, the method including a sacrificial layer forming step of forming a sacrificial layer on a piezoelectric substrate, a dielectric film forming step of forming a dielectric film including SiO₂ as a main component, and having a refractive index of 1.468 or more and 1.471 or less on the piezoelectric substrate and the sacrificial layer, a joining step of joining the dielectric film and the support substrate, a film thinning step of thinning the piezoelectric substrate, and obtaining a piezoelectric layer, and a removing step of removing the sacrificial layer, and forming a hollow part between the support substrate and the piezoelectric layer.

### Advantageous Effects of Invention

It is possible to provide a joined body including a desired hollow part. Further, it is possible to provide a method for manufacturing a joined body in which the difference in etching rate from the sacrificial layer is large, and by which the sacrificial layer can be selectively removed during etching.

### BRIEF DESCRIPTION OF DRAWINGS

FIG. 1 is a view showing a joined body of the present embodiment.

FIG. 2 is a flowchart for illustrating a method for manufacturing a joined body.

FIGS. 3A to 3E are each a view showing the state corresponding to each step shown in FIG. 2.

FIG. 4 is a view showing a reactive sputtering apparatus for use in forming a dielectric film.

FIG. 5 is a view showing the etching rates at levels 1 to 16.

FIG. 6 is a view showing the relationship between the oxygen radical discharge output and the etching rate.

FIG. 7 is a view showing the relationship between the flow rate of an argon gas and the etching rate.

FIG. 8 is a view showing the relationship between the refractive index of SiO₂ and the etching rate.

### DESCRIPTION OF EMBODIMENTS

Below, referring to the accompanying drawings, embodiments of the present invention will be described in details.

### <Description of Configuration of Joined Body>

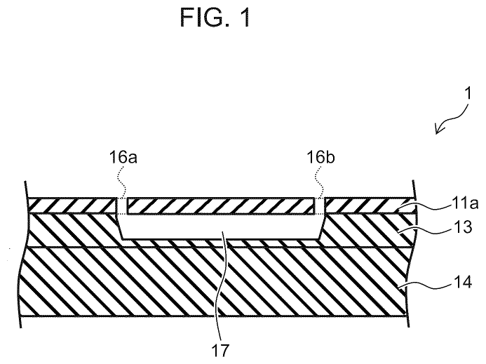

FIG. 1 is a view showing a joined body 1 of the present embodiment.

The shown joined body 1 has a structure in which a piezoelectric layer 11a, a dielectric film 13, and a support substrate 14 are stacked in this order from the upper part in the drawing. Further, a hollow part 17 is provided between the support substrate 14 and the piezoelectric layer 11a.

The piezoelectric layer 11a is a layer including a piezoelectric material. The piezoelectric material is selected according to the application in which the joined body 1 is used. The piezoelectric materials may include, but are not limited to, for example, LiNbO₃ (LN) and LiTaO₃ (LT). Silicon (Si), gallium arsenide (GaAs), silicon carbide (SiC), gallium nitride (GaN), zinc oxide (ZnO), solid solution ceramics (PZT), or the like is appropriately selected.

The dielectric film 13 is the layer to be arranged under the piezoelectric layer 11a. Although described particularly later, the dielectric film 13 includes SiO₂ as the main component. Namely, the dielectric film 13 can also be said to be a SiO₂ film or a SiO₂ layer. Further, the dielectric film 13 has a H (hydrogen) content of 0% or more and 1% or less in terms of atomic ratio. Still further, for the dielectric film 13 including SiO₂ as the main component, the refractive index of SiO₂ is preferably 1.468 or more and 1.471 or less. A refractive index falling within this range facilitates control of the etching rate to 200 nm/min or less. Incidentally, the measurement of the refractive index of SiO₂ can be performed by means of, for example, a spectroscopic ellipsometer, and a wavelength of 633 nm can be used.

The support substrate 14 will serve as the support of the whole joined body 1. Further, the support substrate 14 is joined with the piezoelectric layer 11a via the dielectric film 13. As the support substrate 14, a given proper substrate can be used. The support substrate 14 may include a single crystalline body, or may include a polycrystalline body. Alternatively, the support substrate 14 may include a metal.

The material configuring the support substrate 14 is preferably selected from the group consisting of silicon, SiAlON, sapphire, cordierite, mullite, glass, quartz, rock crystal, alumina, SUS, iron nickel alloy (42 alloy), and brass. Although the thickness of the support substrate 14 is, for example, 0.3 to 1 mm, another given proper thickness than these can be adopted.

The silicon may be single crystal silicon, may be polycrystal silicon, or may be high resistance silicon. Alternatively, the support substrate 14 may be SOI (Silicon on Insulator).

Typically, the SiAlON is ceramics obtained by sintering the mixture of silicon nitride and alumina, and has, for example, a composition represented by Si_{6-w}Al_{w}O_{w}N_{8-w}. Specifically, SiAlON has a composition obtained by mixing alumina in silicon nitride, and w in the formula represents the mixing ratio of alumina. w is preferably 0.5 or more and 4.0 or less.

Typically, the sapphire is a single crystalline body having the composition of Al₂O₃, and the alumina is a polycrystalline body having the composition of Al₂O₃. Alumina is preferably translucent alumina.

Typically, the cordierite is ceramics having a composition of 2MgO·2Al₂O₃·5SiO₂, and the mullite is ceramics having a composition within the range of 3Al₂O₃·2SiO₂ to 2Al₂O₃·SiO₂.

The hollow part 17 is formed at the concave part provided at the dielectric film 13 in the present embodiment. Hole parts 16a and 16b are formed in the piezoelectric layer 11a, and the hole parts 16a and 16b communicate with the hollow part 17.

### <Device>

The structure of the shown joined body 1 can be used as each structure of various devices. Examples of the device may include a high-frequency device, a power semiconductor, a semiconductor laser, a surface acoustic wave filter (SAW (Surface Acoustic Wave) filter), and a thin film piezoelectric MEMS (Micro Electro Mechanical Systems).

### <Description of Method for Manufacturing Joined Body 1>

Next, a method for manufacturing the joined body 1 will be described.

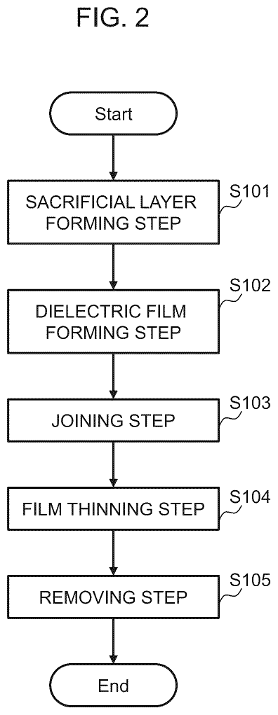

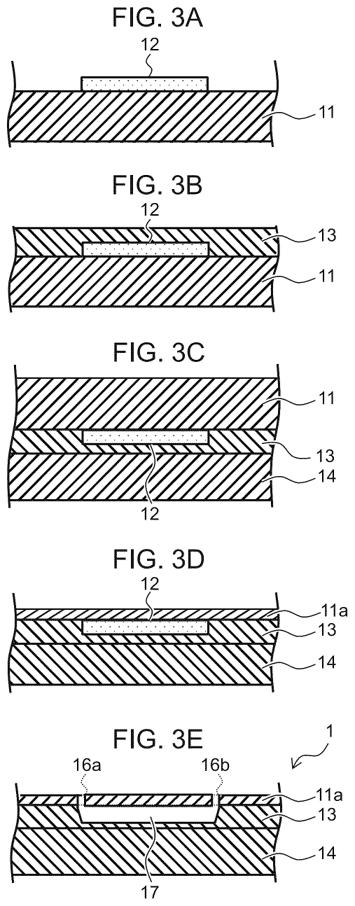

FIG. 2 is a flowchart for illustrating the method for manufacturing the joined body 1. Further, FIGS. 3A to 3E are each a view showing the state corresponding to each step shown in FIG. 2.

First, a piezoelectric substrate 11 is prepared, and a sacrificial layer 12 is formed at the piezoelectric substrate 11 (Step 101: sacrificial layer forming step) (FIG. 3A). The sacrificial layer 12 becomes the hollow part 17 by being removed by a later step. Accordingly, the sacrificial layer 12 is formed at the site where the hollow part 17 is desired to be formed. The sacrificial layer 12 can be formed as a metal such as Ni, Cu, Al, or Si, an insulation film of SiO₂, ZnO, PSG (phosphosilicate glass), or the like, an organic film, or the like. The sacrificial layer 12 can be formed by vacuum evaporation, sputtering, CVD, spin coating, or the like.

Further, on the piezoelectric substrate 11 and the sacrificial layer 12, the dielectric film 13 including SiO₂ as the main component, and having a H content of 0% or more and 1% or less in terms of atomic ratio is formed (Step 102: dielectric film forming step) (FIG. 3B). In this case, the dielectric film 13 is formed in such a manner as to cover the piezoelectric substrate 11 and the sacrificial layer 12. The formation method of the dielectric film 13 will be described in details later.

Next, the support substrate 14 is prepared, and the dielectric film 13 and the support substrate 14 are joined (Step 103: joining step) (FIG. 3C). The step is performed by using, for example, the Plasma Activated Bonding (PAB) method in which the joint surface between the dielectric film 13 and the support substrate 14 is subjected to a surface treatment in vacuum for activation, thereby joining both at ordinary temperatures. Incidentally, when the dielectric film 13 and the support substrate 14 are joined, a dielectric film (SiO₂) is deposited on a part of the support substrate 14, and the partial dielectric film deposited on the support substrate 14, and the dielectric film 13 formed on the piezoelectric substrate 11 may be subjected to Plasma Activated Bonding.

Then, the piezoelectric substrate 11 is polished, thereby forming the piezoelectric layer 11a (Step 104) (FIG. 3D.

Incidentally, the following method can also be used. At Step 101, hydrogen ions or helium ions are injected into the surface of the piezoelectric substrate 11, and at Step 104, the site at the depth at which the ions have been injected is set as a separation surface, thereby separating the piezoelectric substrate 11a. In the present embodiment, any method may be adopted. Even when any method is adopted, the Step 104 can be grasped as a film thinning step of thinning the piezoelectric substrate 11, and obtaining the piezoelectric layer 11a.

In order to allow the joined body 1 to function as a surface acoustic wave filter, an upper electrode and an IDT (Interdigital Transducer) electrode may be formed on the piezoelectric layer 11a. The electrodes are manufactured by using a conductive material such as Al (aluminum). The electrodes can be formed by, for example, the vacuum evaporation lift method.

Further, the sacrificial layer 12 is removed, and the hollow part 17 is formed between the support substrate 14 and the piezoelectric layer 11a (Step 105: removing step) (FIG. 3E). In order to perform this, first, the resist film is patterned by photolithography. Then, an etching gas is allowed to flow thereinto, thereby forming the hole parts 16a and 16b. The hole parts 16a and 16b penetrate through the piezoelectric layer 11a, and reach the sacrificial layer 12. Then, an etching gas or an etchant is allowed to flow thereinto via the hole parts 16a and 16b, thereby removing the sacrificial layer 12. As a result of this, the site where the sacrificial layer 12 is formed becomes the hollow part 17. Namely, the sacrificial layer 12 is removed by dry etching or wet etching, thereby forming the hollow part 17.

Further, after the step of FIG. 3E, a protective layer including an insulation film can be formed on the piezoelectric layer 11a, the upper electrode, or the IDT electrode. Furthermore, an external terminal may be formed at the upper electrode, or the IDT electrode.

With the steps up to this point, FIGS. 3D and 3E can be grasped as the joined body of the present embodiment.

### <Formation Method of Dielectric Film 13>

Next, the formation method of the dielectric film 13 will be described in details.

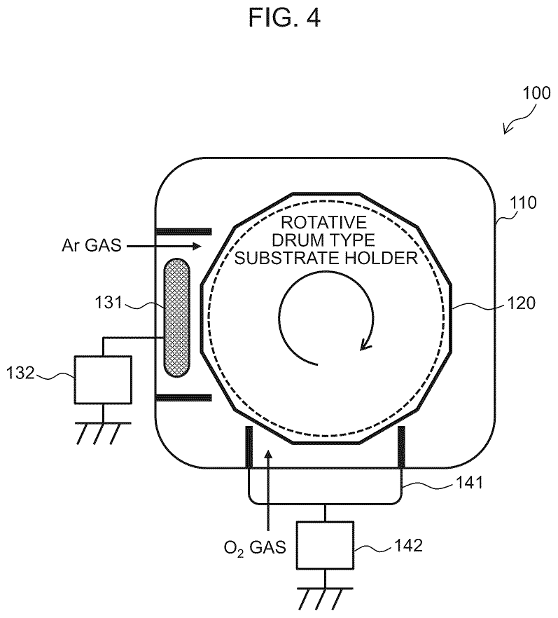

FIG. 4 is a view showing a reactive sputtering apparatus 100 to be used for forming the dielectric film 13. Namely, FIG. 4 is an apparatus to be used for performing the Step 102 of FIG. 2, and the step of FIG. 3B.

The shown reactive sputtering apparatus 100 includes a chamber 110, a rotative drum type substrate holder 120 to be arranged in the chamber 110, a target 131 to be arranged in the reactive sputtering apparatus 100, a sputtering power supply 132, a radical oxidation source 141, and a radical source power supply 142.

The reactive sputtering apparatus 100 is an apparatus for performing reactive sputtering using silicon (Si) as the target 131, using an oxygen (O₂) gas and an argon (Ar) gas. The piezoelectric substrate 11 (FIG. 3A) including the sacrificial layer 12 formed thereon is arranged at the rotative drum type substrate holder 120. In this case, while an argon gas is introduced as it is into the chamber 110, an oxygen gas is previously made into radicals by the radical oxidation source 141, and is introduced as oxygen radicals into the chamber 110. Then, silicon configuring the target 131 is sputtered by the sputtering power supply 132, and a silicon film is formed on the piezoelectric substrate 11 and the sacrificial layer 12. This is oxidized by oxygen radicals, resulting in a silicon oxide (SiO₂) film. As a result of this, it is possible to form the dielectric film 13 including SiO₂ as the main component. Further, a plurality of objects for deposition can be set at the rotative drum type substrate holder 120. By changing the deposition conditions while rotating the rotative drum type substrate holder 120, it is possible to form a dielectric film 13 under various deposition conditions. The deposition conditions include the flow rate of an argon gas, the flow rate of an oxygen gas, the oxygen radical discharge output, and the sputtering discharge output.

In the present embodiment, the dielectric film 13 including SiO₂ as the main component, and having a H content of 0% or more and 1% or less in terms of atomic ratio is formed. From the viewpoints of making the dielectric film 13 less likely to be etched, and facilitating selective etching of the sacrificial layer 12, the H content is preferably 0.1% or more and 1.0% or less, and more preferably 0.2% or more and 0.9% or less. In order to obtain such a dielectric film 13, for example, at least one of the following (1) and (2) is preferably used as the deposition condition.
(1) The discharge output of oxygen radicals is 1 or more and 1.5 or less in terms of the ratio when 3000 W is assumed to be the standard. Namely, the discharge output of oxygen radicals is set at 3000 W or more and 4500 W or less.
(2) The flow rate for introducing an argon gas is 0.81 or more and 1 or less in terms of the ratio when 400 sccm (Standard Cubic Centimeter per Minute) is assumed to be the standard. Namely, the flow rate of an argon gas is set at 324 sccm or more and 400 sccm or less. Incidentally, sccm means the gas flow rate (cm³/min) when converted into the value at 1 atm, and 0° C.

As a result of this, it is possible to form the dielectric film 13 with a low etching rate. Further, this can be also said that it is possible to form the dielectric film 13 with a large difference in etching rate from the sacrificial layer 12. In consequence, it is possible to provide the joined body 1 including the hollow part 17 with a desired size at a desired position. Furthermore, it is possible to provide a method for manufacturing a joined body with a large difference in etching rate from the sacrificial layer 12, the method being capable of selectively removing the sacrificial layer 12 during etching.

### EXAMPLES

### <Manufacturing of Dielectric Film 13>

Using the reactive sputtering apparatus 100 shown in FIG. 4, under the deposition conditions shown in Table 1 below, the dielectric film 13 including SiO₂ was manufactured. Incidentally, the thickness of the dielectric film 13 was set at 500 nm. Incidentally, the case where the discharge output of oxygen radicals is 3000 W, or the case where the flow rate for introducing an argon gas is 400 sccm may be referred to as the standard condition.

The following Table 1 shows the ratio of each parameter when the standard condition is assumed to be 1. Incidentally, the flow rate of an oxygen gas and the sputtering discharge output were set uniform.

As shown in Table 1, the dielectric films 13 were formed under 16 different deposition conditions of levels 1 to 16. Out of these, the levels 1 to 4, 11, and 16 satisfy both the deposition conditions of the (1) and (2). Whereas, although the levels 5, 8, 12, 13, and 15 satisfy the deposition condition of the (2), they do not satisfy the deposition condition of the (1). Further, although the levels 6, 7, and 10 satisfy the deposition condition of the (1), they do not satisfy the deposition condition of the (2). Still further, the levels 9 and 14 satisfy neither of the deposition conditions of the (1) and (2).

TABLE 1

| | Ar flow | Oxygen radical |
|---|---|---|
| Level | rate | discharge output |
| 1 (Standard) | 1.00 | 1.00 |
| 2 | 0.81 | 1.00 |
| 3 | 0.81 | 1.50 |
| 4 | 1.00 | 1.50 |
| 5 | 1.00 | 0.80 |
| 6 | 1.19 | 1.20 |
| 7 | 1.19 | 1.00 |
| 8 | 1.00 | 0.50 |
| 9 | 1.19 | 0.50 |
| 10 | 1.19 | 1.50 |
| 11 | 0.81 | 1.20 |
| 12 | 0.81 | 0.40 |
| 13 | 0.81 | 0.80 |
| 14 | 1.19 | 0.40 |
| 15 | 0.81 | 0.50 |
| 16 | 0.95 | 1.00 |

### <Evaluation>

Buffered hydrofluoric acid was used for etching whose etching rate of the dielectric film 13 was evaluated. The thicknesses of the dielectric film 13 before and after etching were calculated using a spectroscopic ellipsometer, and the etching rate was calculated from the difference in film thickness and the etching time. At this step, the case where the etching rate was 200 nm/min or less was rated as success, and the case where the etching rate exceeded 200 nm/min was rated as failure.

### <Evaluation Results>

Below, the evaluation results will be described.

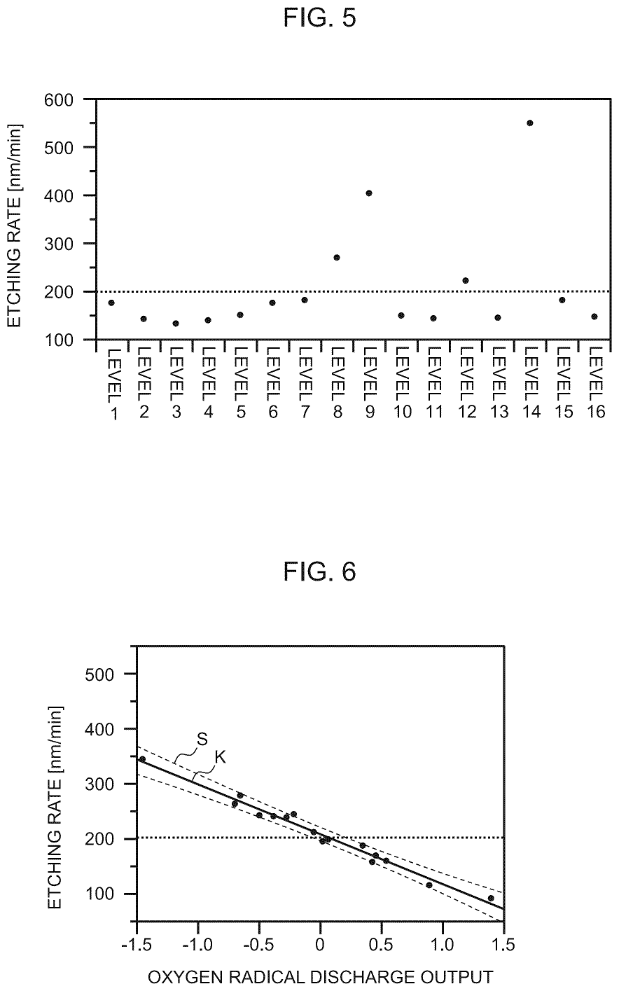

FIG. 5 is a view showing each etching rate of levels 1 to 16.

In FIG. 5, the horizontal axis represents the levels 1 to 16, and the vertical axis represents the etching rate of the dielectric film 13.

As shown in FIG. 5, at the levels 8, 9, 12, and 14, each etching rate of the dielectric films 13 exceeded 200 nm/min, and hence each result was a failure. The dielectric films 13 can be said to tend to be etched with the sacrificial layer 12 during etching.

In contrast, in other cases, each etching rate was 200 nm/min or less, and the result was a success. It can be said that the dielectric films 13 are less likely to be etched, and that the sacrificial layer 12 tends to be selectively etched.

Accordingly, it can be said as follows: the levels 1 to 7, 10, 11, 13, and 15 to 16 are Examples in the present invention, and the levels 8, 9, 12, and 14 are Comparative Examples in the present invention.

Using the results of FIG. 5, regression analysis was performed, thereby acquiring the leverage plot of each deposition parameter. As a result, the following relationship could be obtained.

FIG. 6 is a view showing the relationship between the oxygen radical discharge output and the etching rate.

In FIG. 6, the horizontal axis represents the oxygen radical discharge output, and the vertical axis represents the etching rate.

FIG. 6 shows the regression curve K and the reliability curve S with respect to the regression straight line. According to this, the etching rate can be said to depend upon the oxygen radical discharge output.

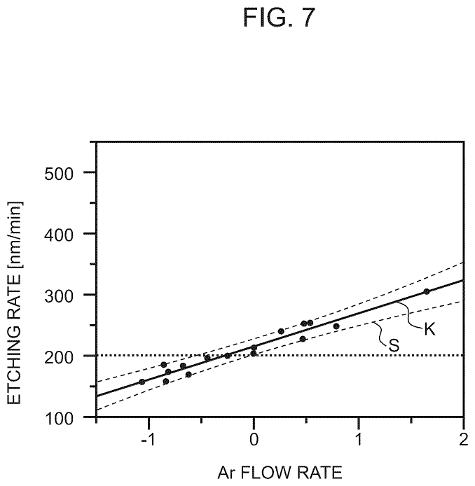

FIG. 7 is a view showing the relationship between the flow rate of an argon gas and the etching rate.

In FIG. 7, the horizontal axis represents the flow rate of an argon gas (shown as the Ar flow rate), and the vertical axis represents the etching rate.

In FIG. 7, the regression curve K and the reliability curve S with respect to the regression straight line are indicated with dotted lines. According to this, the etching rate can be said to depend upon the flow rate of an argon gas.

Further, the composition of each dielectric film 13 of the levels 1, 3, 7, 8, 12, 14, 15, and 16 was analyzed by RBS (Rutherford Backscattering Spectrometry).

The results are shown in the following Table 2.

TABLE 2

| | Etching rate | Si | H | O | Ar |
|---|---|---|---|---|---|
| Level | [mm/min] | [%] | [%] | [%] | [%] |
| 3 | 136.5 | 33.8 | 0.2 | 65.5 | 0.50 |
| 16 | 170.2 | 32.8 | 0.4 | 66.0 | 0.77 |
| 1 (Standard) | 179.2 | 33.0 | 0.7 | 65.9 | 0.42 |
| 15 | 183.8 | 33.5 | 0.7 | 65.4 | 0.40 |
| 7 | 185.4 | 33.1 | 0.9 | 65.6 | 0.40 |
| 12 | 223.8 | 33.1 | 1.2 | 65.0 | 0.70 |
| 8 | 272.7 | 33.0 | 1.4 | 65.2 | 0.39 |
| 14 | 544.8 | 30.6 | 5.9 | 63.0 | 0.50 |

According to Table 2, the H content increased with an increase in etching rate, and more than 1% as at the level 8 resulted in an etching rate about 1.5 times that of the standard condition.

When etching for forming the hollow part 17 is performed, the dielectric film 13 including SiO₂ with a low etching rate is desirable in order to make a large difference in etching rate from the sacrificial layer 12. The results of this time indicate that the H content in SiO₂ is desirably set at 0% or more and 1% or less for obtaining the dielectric film 13 with an etching rate of 200 nm/min or less. Further, a higher oxygen radical discharge output results in more difficulty of etching (FIG. 6), and a condition of a lower flow rate of an argon gas results in more difficulty in etching (FIG. 7). When the oxygen radical discharge output is set at 3000 W as the standard condition, and the standard condition is referred to as 1, the oxygen radical discharge output is preferably 1 or more and 1.5 or less. On the other hand, when the flow rate of an argon gas is set at 400 sccm as standard, and the standard condition is referred to as 1, the oxygen radical discharge output is preferably 0.81 or more and 1 or less. Furthermore, when both of the deposition conditions are satisfied regarding the oxygen radical discharge output and the flow rate of an argon gas, the etching rate is further reduced, which is further preferable as the deposition condition.

### <Relationship Between Refractive Index of SiO₂ and Etching Rate>

The refractive index of SiO₂ deposited as the dielectric film 13 under the deposition condition of this time was measured. The measurement of the refractive index was performed with a spectroscopic ellipsometer, and the refractive index at a wavelength of 633 nm was acquired.

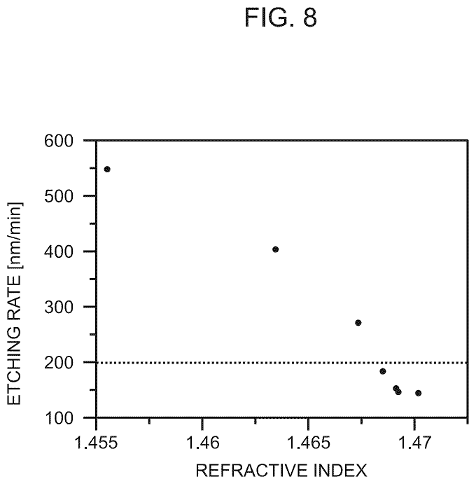

FIG. 8 is a view showing the relationship between the refractive index of SiO₂ and the etching rate.

FIG. 8 indicates that the refractive index of SiO₂ and the etching rate are correlated with each other. For obtaining a 200-nm/min dielectric film 13, the refractive index is preferably 1.468 or more and 1.471 or less.

Up to this point, the present embodiment was described. However, the technical scope of the present invention is not limited to the scope described in the embodiments. It is obvious from the appended claims that variously changed or improved embodiments described above are also included in the technical scope of the present invention.

### REFERENCE SIGNS LIST

1 Joined body
11 Piezoelectric substrate
11a Piezoelectric layer
12 Sacrificial layer
13 Dielectric film
14 Support substrate
17 Hollow part

1. A joined body comprising:
a piezoelectric layer including a piezoelectric material;
a dielectric film arranged under the piezoelectric layer;
a support substrate joined with the piezoelectric layer via the dielectric film; and
a sacrificial layer provided between the support substrate and the piezoelectric layer, and capable of including a hollow part formed therein, wherein
the dielectric film includes SiO₂ as a main component, and has a H content of 0.1% or more and 1.0% or less in terms of atomic ratio.

2. The joined body according to claim 1, wherein
the dielectric film includes SiO₂ as a main component, and has a refractive index of 1.468 or more and 1.471 or less.

3. A joined body comprising:
a piezoelectric layer including a piezoelectric material;
a dielectric film arranged at the piezoelectric layer;
a support substrate joined with the piezoelectric layer via the dielectric film; and
a hollow part provided between the support substrate and the piezoelectric layer, wherein
the dielectric film includes SiO₂ as a main component, and has a H content of 0.1% or more and 1.0% or less in terms of atomic ratio.

4. A method for manufacturing a joined body, the method comprising:
a sacrificial layer forming step of forming a sacrificial layer on a piezoelectric substrate;
a dielectric film forming step of forming a dielectric film including SiO₂ as a main component, and having a H content of 0.1% or more and 1.0% or less in terms of atomic ratio on the piezoelectric substrate and the sacrificial layer;
a joining step of joining the dielectric film and a support substrate;
a film thinning step of thinning the piezoelectric substrate, and obtaining a piezoelectric layer; and
a removing step of removing the sacrificial layer, and forming a hollow part between the support substrate and the piezoelectric layer.

5. The method for manufacturing a joined body according to claim 4, wherein
the dielectric film forming step uses silicon as a target, and forms the dielectric film using a reactive sputtering apparatus for introducing an oxygen radical and an argon gas, and
a discharge output of the oxygen radical is 1 or more and 1.5 or less when 3000 W is assumed to be a standard.

6. The method for manufacturing a joined body according to claim 4, wherein
the dielectric film forming step uses silicon as a target, and forms the dielectric film using a reactive sputtering apparatus for introducing an oxygen radical and an argon gas, and
a flow rate for introducing the argon gas is 0.81 or more and 1 or less in a ratio thereof when 400 sccm (Standard Cubic Centimeter per Minute) is assumed to be the standard.
